(19) United States
(12) Patent Application Publication
(10) Pub. No.: US 2026/0202456 A1
(43) Pub. Date: Jul. 16, 2026

(54) METHOD FOR DETECTING AN ELECTRICAL FAULT IN A CABLE NETWORK OF A HARNESS AND ASSOCIATED DEVICE

(71) Applicant: Safran Nacelles, GONFREVILLE-L'ORCHER (FR)

(72) Inventors: David PEREIRA, MOISSY-CRAMAYEL (FR); Thibault DELESALLE, MOISSY-CRAMAYEL (FR)

(73) Assignee: Safran Nacelles, GONFREVILLE-L'ORCHER (FR)

(21) Appl. No.: 19/134,396

(22) PCT Filed: Nov. 29, 2023
(86) PCT No.: PCT/FR2023/051867

§ 371 Date: May 30, 2025

(30) Foreign Application Priority Data
Dec. 1, 2022 (FR) FR2212614

(51) Int. Cl. G01R 31/00; G01R 31/52

(52) U.S. Cl. CPC G01R 31/008; G01R 31/52

(57) ABSTRACT

A method for detecting an electrical fault in a harness of an aircraft includes connecting the harness to multiplexers of a device for detecting an electrical fault, powering an anode of a first diode of the device at a first potential and an anode of a second diode of the device at a second potential, and at each iteration of plural iterations, performing the operations of selecting an address for each multiplexer, calculating a potential difference between a cathode of the first diode and a cathode of the second diode, and determining an electrical fault in the harness from the potential difference.

### FIELD OF THE INVENTION

The invention relates to the field of the maintenance of onboard systems of an aircraft. In particular, the invention relates to the maintenance of an electrical harness of an aircraft.

### PRIOR ART

A turbomachine has a main direction extending along a longitudinal axis, and typically includes, from upstream to downstream in the direction of flow of the gas, a fan and a primary spool including a compression section which may comprise a low-pressure compressor, a high-pressure compressor, a combustion chamber, and a turbine section which may comprise a high-pressure turbine and a low-pressure turbine. In particular, so-called twin spool turbomachines comprising a low-pressure shaft and a high-pressure shaft are equipped with sensors serving to measure the rotation speed of the low-pressure shaft and the rotation speed of the high-pressure shaft.

An electrical harness is an electrical device which conveys electrical signals between different items of equipment. In the case of the turbomachine equipped with electronic control units and numerous sensors, electrical harnesses are placed between the electronic control unit and the sensors so as to convey—to the electronic control unit—the measurements taken by these sensors, for example the measurements taken from the low-pressure and high-pressure shafts. The harness comprises a network of electrically insulated wires protected from external electromagnetic disturbances by shielding devices and insulating sheaths and comprises a number of terminations (connectors, pods etc.) between different ends.

In the event of a malfunction of the harness, two types of tests to check the correct operation of the electrical harness are performed manually by a mechanic. A measurement of the electrical continuity of each end of the harness, to make sure that there are no cut wires, and a measurement of the insulation over all the connectors of the harness to make sure that there is no short-circuit between the wires and between the wires and the shielding.

However, this method can be lengthy if the number of wires to be tested is large. In addition, there is a risk of the mechanic in charge of maintenance performing an incorrect manipulation or forgetting to test one or more wires.

### SUMMARY OF THE INVENTION

An aim of the invention is therefore to automate the detection of malfunctions in a harness in order to improve the reliability and speed of execution of a maintenance operation on the harness.

For this purpose, according to a first aspect of the invention, provision is made for a method for detecting an electrical fault in a cable network electrically connecting a first termination and a second termination of an electrical harness of an aircraft, the method comprising the following steps:
E1: connecting the cable network to the channels of a first multiplexer and of a second multiplexer of a device for detecting an electrical fault of the harness;
E2: supplying an anode of a first diode of the device at a first potential and an anode of a second diode of the device at a second potential different from the first potential; the method comprising, at each iteration of a plurality of iterations, the performance of the following steps:
E41: selecting a first address of the first multiplexer and a second address of the second multiplexer;
E42: computing a potential difference between a cathode of the first diode and a cathode of the second diode; and
E43: deducing from the potential difference the existence of an electrical fault in the cable network.

Thus, such a method allows the mechanic to save time when searching for malfunctions. The time saved by the mechanic is estimated at between 25% to 92% of the duration of a maintenance operation without implementing the method depending on the number of wires tested.

A better diagnostic of the state of operation of the electrical harnesses is also possible, allowing a reduction of the maintenance costs related to the return of an electrical harness in good working condition to the supplier.

Provision can moreover be made for a step E3 of configuring the addresses of the channels of the first and second multiplexers, each address corresponding to a separate wire of the cable network.

Provision can also be made for a step E21 in which wires of the cable network are electrically connected to a single node.

Provision can moreover be made for a step E22 of selecting a detection mode of the device, for example a short circuit detection mode and/or an open circuit detection mode.

Provision can be made for the channels of the multiplexers to be configured by loading a wiring diagram of the harness recorded in a database.

Provision can moreover be made for a step E421 of recording the addresses and the potential difference.

Provision can be made for the plurality of iterations to be at least equal to the number of possible combinations of a channel of the first multiplexer with a channel of the second multiplexer.

Provision can be made for the wires identified as being in an open circuit and/or a short-circuit to be displayed, for example on a simplified wiring diagram of the electrical harness.

Provision can be made for the wires identified as being in an open circuit and/or a short circuit to be recorded, for example in a file.

According to a second aspect of the invention, provision is made for a device for detecting an electrical fault in a cable network electrically connecting a first termination and a second termination of an electrical harness of an aircraft comprising:
a connection interface configured to connect the cable network to the detection device;
a first multiplexer and a second multiplexer configured to be electrically connected to the cable network;
a processing unit comprising a first input and a second input, the first input and the second input being configured to be electrically connected to the first multiplexer and to the second multiplexer respectively;
a first diode comprising a first anode configured to be connected to a voltage source at a first potential and a first cathode configured to be electrically connected to an output of the first multiplexer and the first input of the processing unit; and
a second diode comprising a second anode configured to be connected to a voltage source at a second potential and a second cathode configured to be electrically connected to an output of the second multiplexer and the second input of the processing unit, the second potential being different from the first potential;
the processing unit being configured to:
select a first address of the first multiplexer and a second address of the second multiplexer;
compute a potential difference between the first cathode and the second cathode; and
deduce from the potential difference the existence of an electrical fault in the cable network.

Provision can be made for the device to moreover comprise a means for interconnecting wires of the cable network to a single node.

Provision can be made for the voltage source to be a local source or tapped from an electrical network of the aircraft.

According to a third aspect of the invention, provision is made for a computer program product comprising instructions which, when the program is executed on a processing unit of a device in accordance with the second aspect, lead it to implement the steps E41 to E43 of the method according to the first aspect.

According to a fourth aspect of this summary, provision is made for a storage means readable by a computer, on which the computer program product according to the third aspect is recorded.

### DESCRIPTION OF THE FIGURES

A description will now follow of an embodiment of the invention by way of non-limiting example based on the drawings on which:

FIG. 1 is a diagram of a turbomachine of an aircraft comprising an electrical harness;

FIG. 2 is a diagram of a part of an electrical harness of an aircraft;

FIG. 3 is a diagram of a detection device according to the invention;

FIG. 4 is a flow chart showing the steps of a mode of implementation of the method according to the invention;

FIG. 5 is a simplified wiring diagram of the device of FIG. 3 connected to a harness;

FIG. 6 is a simplified wiring diagram of the device of FIG. 3 electrically connected to a harness comprising wires in a short circuit;

FIG. 7 is an equivalent wiring diagram to FIG. 6;

FIG. 8 is a simplified wiring diagram of the device of FIG. 3 electrically connected to a harness in which the wires are interconnected;

FIG. 9 is an equivalent wiring diagram to FIG. 8; and

FIG. 10 is a simplified wiring diagram of the device of FIG. 3 electrically connected to a harness comprising wires in an open circuit.

On all the figures, similar elements bear identical reference numbers.

### DETAILED DESCRIPTION OF THE INVENTION

A turbomachine 10 has a main direction extending along a longitudinal axis X, and typically includes from upstream to downstream in the direction of flow of the gas, a fan 102, a primary spool including a compression section which may comprise a low-pressure compressor 103 as well as a high-pressure compressor 104, a combustion chamber 105, and a turbine section which may comprise a high-pressure turbine 106 as well as a low-pressure turbine 107. In an embodiment, the fan 102 may be ducted and be housed in a retaining casing and comprises a nacelle 101 defining an aerodynamic container of the engine. In a variant, the fan can be unducted. The air stream entering the turbomachine 10 divides into a primary stream configured to traverse the primary spool and a secondary stream which bypasses the primary spool and is compressed by the fan 102.

Furthermore, the turbomachine 10 can be ducted and comprise more than two spools.

The turbomachine 10 comprises at least two drive shafts, typically a high-pressure shaft 109 and a low-pressure shaft 108.

The high-pressure shaft 109 is connected to the high-pressure turbine 106 and is configured to drive the high-pressure compressor 104.

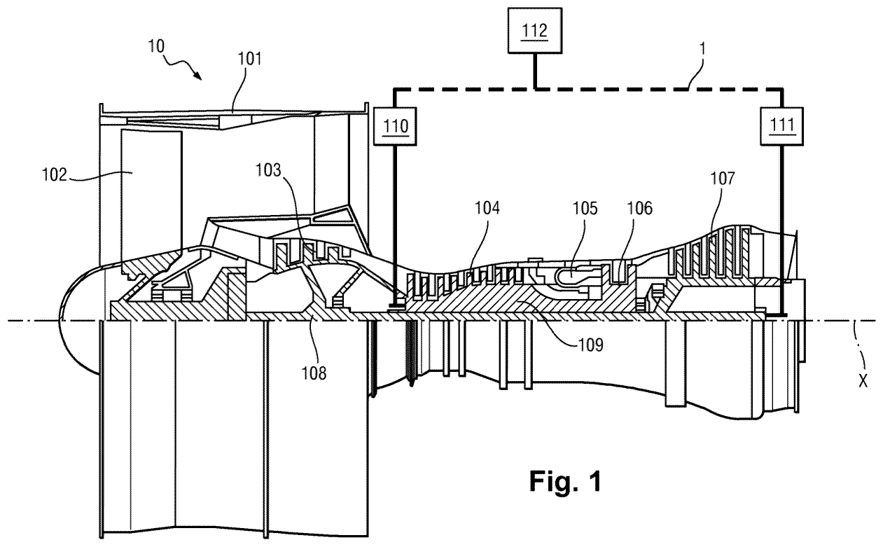

The low-pressure shaft 108 is connected to the low-pressure turbine 107 and is configured to drive the low-pressure compressor 103. The low-pressure shaft 108 rotationally drives the fan 102, either directly by the low-pressure turbine, or by way of a reduction mechanism which may comprise an epicyclic reduction gear of planetary or star type (see FIG. 1).

The invention is also applicable to turbomachines comprising a third shaft connected to an intermediate turbine extending between the high-pressure turbine 106 and the low-pressure turbine 107. The intermediate turbine drives the low-pressure compressor 103. The fan 102 is driven by the low-pressure turbine 107.

In this application, the upstream and the downstream are defined in relation to the normal direction of flow of the gas through the turbomachine 10. Thus, the axis X of the turbomachine 10 corresponds to the axis of rotation of its rotor parts.

The turbomachine 10 also comprises two speed sensors 110 and 111 configured to respectively measure the speed of rotation of the high-pressure shaft 109 and of the low-pressure shaft 108, as well as an electronic control unit 112 electrically connected to the sensors 110, 111.

The turbomachine 10 further comprises an electrical harness 1 comprising a first termination and a second termination at its ends configured to electrically connect the sensors 110 and 111, respectively, to the electronic control unit 112 in the turbomachine 1 by a cable network, each cable comprising one or more wires. The terminations may comprise connectors or pods.

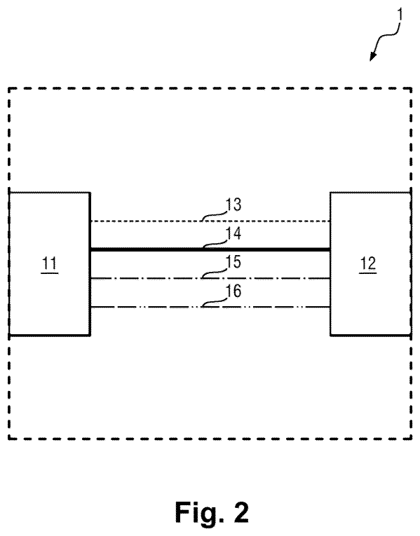

For example, as illustrated in FIG. 2, four wires 13, 14, 15, 16 form a part of the cable network electrically connecting the first termination comprising a first connector 11 and the second termination comprising a second connector 12. The cable network is insulated electrically and from external electromagnetic disturbances by a sheath.

However, the Applicant observed that the electrical harness 11 can be subject to electrical faults, such as a short circuit between two wires or a break in a wire, which are difficult to locate. This fault may have arisen prior to its installation in the turbomachine 100 or during its use.

Thus, to detect an electrical fault, provision is made for a device 2 for detecting an electrical fault in the cable network electrically connecting the first connector 11 and the second connector 12 of the harness 1.

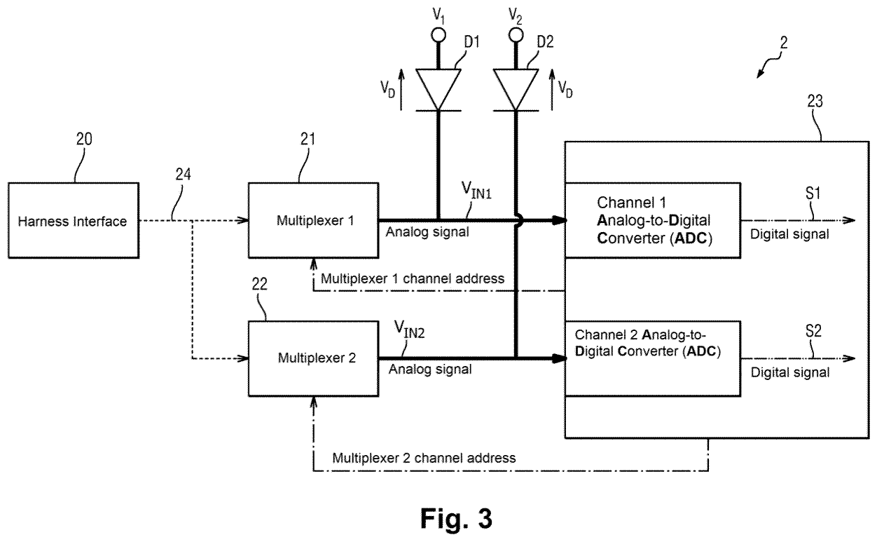

The device 2 for detecting an electrical fault in an electrical harness 1 is illustrated by way of non-limiting example in FIG. 3. The device 2 comprises:
a connection interface 20 (or harness interface) configured to connect the cable network to the detection device 2;
a first multiplexer 21 and a second multiplexer 22 configured to be electrically connected to the cable network;
a processing unit 23 comprising a first input V_{IN1} and a second input V_{IN2}, the first input V_{IN1} and the second input V_{IN2} being configured to be electrically connected to the first multiplexer 21 and to the second multiplexer 22 respectively;
a first diode D1 comprising a first anode A1 configured to be connected to a voltage source V₁ at a first potential and a first cathode C1 configured to be electrically connected to the output of the first multiplexer 21 and the first input V_{IN1} of the processing unit 23; and
a second diode D2 comprising a second anode A2 configured to be connected to a voltage source V₂ at a second potential and a second cathode C2 configured to be electrically connected to the output of the second multiplexer 22 and the second input of the processing unit 23, the second potential V₂ being different from the first potential V₁.

The processing unit 23 is configured to:
select a first address of the first multiplexer 21 and a second address of the second multiplexer 22;
compute a potential difference between the first cathode C1 and the second cathode C2; and
deduce from the potential difference the existence of an electrical fault in the cable network.

In the following text, the invention is particularly described in the case of an electrical harness 1 of a turbomachine 10. This is however non-limiting, the invention being applicable to any harness suitable for an aircraft.

According to an embodiment illustrated in FIG. 3, the connection interface 20 is configured to create an electrical connection 24 between the wires 13, 14, 15, 16, by way of the second connector 12 of the harness 1 and the multiplexers 21, 22.

According to another embodiment, the connection interface 20 can be configured to create an electrical connection 24 directly between the wires 13, 14, 15, 16 and the multiplexers 21, 22. Thus, the test device 2 can be universally connected to any type of electrical harness 1.

The outputs of the interface 20 are connected identically to all the channels of the first multiplexer 21 and of the second multiplexer 22. The addresses transmitted to the multiplexers 21, 22 by the processing unit 23 make it possible to independently choose a first channel of the first multiplexer 21 and a second channel of the second multiplexer 22 each corresponding to one of the wires 13, 14, 15, 16 to be tested. Thus, the multiplexers 21, 22 can selectively transmit an analog signal coming from a single connected channel.

The analog inputs V_{IN1} and V_{IN2} of the processing unit 23 are electrically connected to the outputs of the multiplexer 21 and 22 respectively. An analog-to-digital converter (ADC) is configured to convert the analog signals into digital signals and the processing unit 23 is configured to compute a potential difference between the two analog signals. The processing unit 23 is moreover configured to perform other mathematical and/or statistical operations such that recurring malfunctions for one and the same family of harnesses are highlighted. Thus, the identification of malfunctions is improved.

The processing unit 23 also comprises two outputs S1 and S2. It is therefore possible to view the signals output by the processing unit 23, for example on a screen.

The command unit 23 can for example be a microcontroller, an FPGA, or any other equivalent electrical component.

The potential difference imposed between the cathodes C1, C2 of the diodes D1, D2 makes it possible to detect a fault. Specifically, in the event of a short circuit between two wires of the harness 1, the two cathodes C1, C2 are electrically connected when the processing unit 23 selects the two channels in a short circuit. In the scenario where, for example, the voltage V₁ is greater than the voltage V₂, the diode D1 is on and the diode D2 is off (the current flows from the highest potential to the lowest potential), simultaneously imposing on the analog inputs V_{IN1}, V_{IN2} of the processing unit 23 the cathode potential of the diode D1. In this case, the potential difference between the cathodes of D1 and D2 has a value of zero and therefore allows the detection of the short circuit.

In the scenario of a detection of an open circuit, the device may comprise a means 24 for interconnecting wires 13, 14, 15, 16 of the cable network to a single node imposing a zero potential difference between V_{IN1} and V_{IN2}, unless one of the wires 13, 14, 15, 16 is no longer interconnected between the first connector 11 and the second connector 12.

Thus, such a set-up of the two diodes D1 and D2 of the device 2 offers the advantage of being a cost-effective detection set-up, but also of being passive since it does not require any controlling of the detection means.

The device 2 is supplied at the potentials V₁ and V₂, respectively at the anodes A1, A2 of each diode D1 and D2, by a voltage source which can be local, for example a battery or a power supply station, or tapped from an electrical network of the aircraft.

For example, the electrical network of the aircraft is a 115V/400 Hz three-phase AC network.

Thus, the device 2 offers the advantage of being nomadic. It can be used interchangeably on an electrical harness 1 outside its installation area, for example the turbomachine 10, or else in its installation area (FIG. 1) simply by unplugging a connector. Reducing the amount of handling also offers the benefit of making maintenance operations on a damaged harness more reliable.

### Method for Detecting an Electrical Fault in the Harness 1

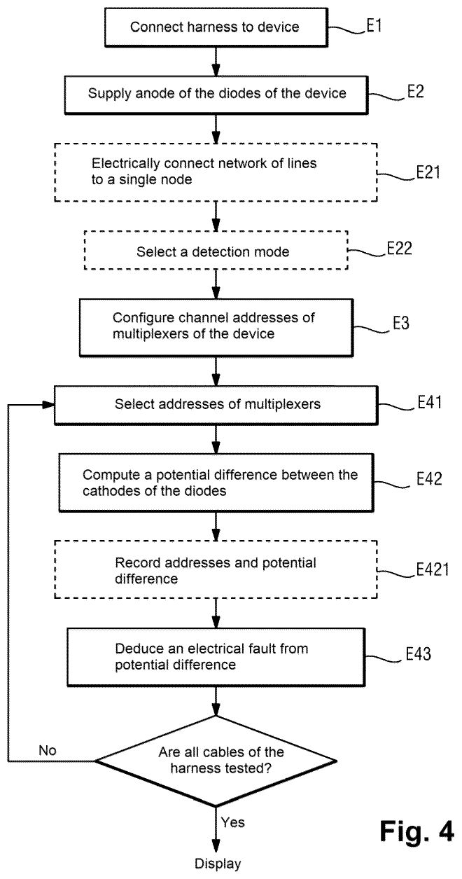

The electrical fault can be a short circuit or an open circuit in the electrical harness 1. To detect such faults, the device 2 can be used by implementing the following steps indicated in FIG. 4.

During a step E1, the cable network is connected to the channels of the first multiplexer 21 and of the second multiplexer 22 of the device 2.

During a step E2, the anode A1 of the first diode D1 of the device 2 is supplied at a first potential V1 and the anode A2 of a second diode D2 of the device 2 is supplied at a second potential V2 different from the first potential V1.

Provision can moreover be made for a step E21, in which the wires 13, 14, 15, 16 of the cable network are electrically connected to a single node, for example manually and/or by an interconnection device 24 configured for the implementation of the step offering the advantage of connecting and/or separating the cable network simply and quickly.

At this stage, the device 2 is connected up to the cable network of the electrical harness 1, either via the connection interface 20 or by any other means, and supplied either by the internal electrical network of the turbomachine 10, if the maintenance or repair operation is being done on an electrical harness 1 connected up to the turbomachine 10, or by an external power supply (battery, national grid etc.), if the operation is being done on an electrical harness 1 removed from the turbomachine 10.

The device 2 is therefore ready for use.

Provision can also be made for a step E22, in which a detection mode of the device 2 is selected, for example a mode of detection of short circuits and/or a mode of detection of an open circuit. Thus, selecting a detection mode allows the processing unit 23 to reduce the number of operations to be performed and therefore increase the computing speed.

During a step E3, the addresses of the channels of the first and second multiplexers 21, 22 are configured, each address corresponding to a separate wire 13, 14, 15, 16.

During the configuration of the addresses, a wiring diagram of the harness 1 being tested is loaded from a database of the device. Thus, the association of the channels of the multiplexers 21, 22 and the wires 13, 14, 15, 16 of the harness 1 is equivalent to the reality of the tested harness 1.

At each iteration of a plurality of iterations, the following steps are performed.

The plurality of iterations can for example be at least equal to the number of possible combinations of a channel of the first multiplexer 21 with a channel of the second multiplexer 22.

The plurality of iterations can be reduced by first testing only the possible combinations of a channel of the first multiplexer 21 with a channel of the second multiplexer 22 if these channels correspond to the nearest wires.

During the steps E41 and E42, a first address of the first multiplexer 21 and a second address of the second multiplexer 22 are then selected to compute a potential difference between the cathode C1 of the first diode D1 and the cathode C2 of the second diode D2.

Provision can also be made for a step E421 in which the addresses of the tested channels and the potential difference computed for these channels are recorded.

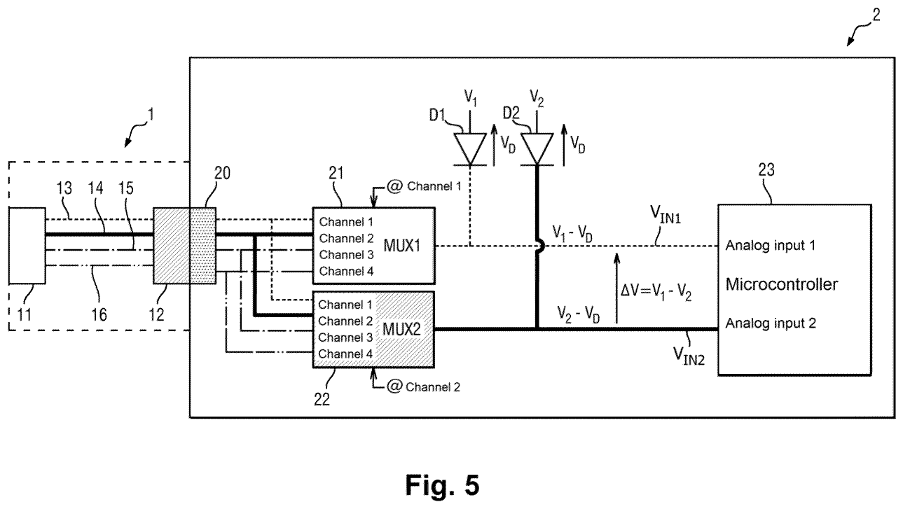

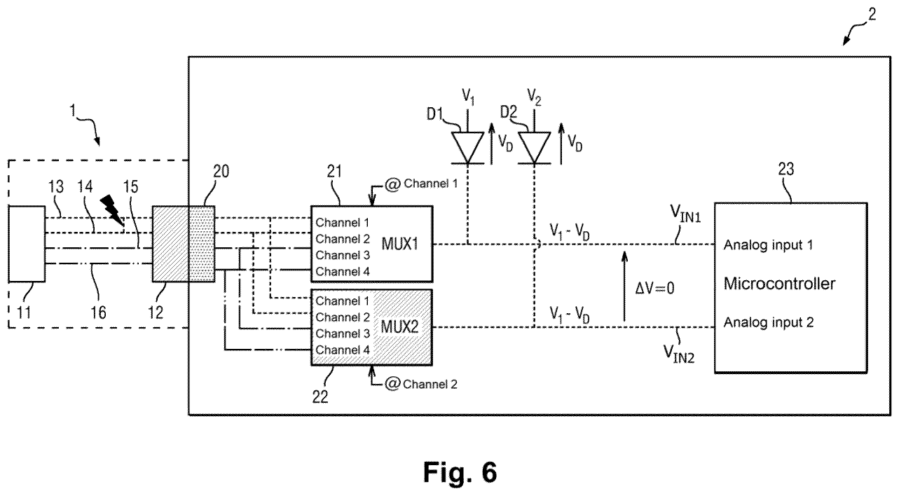

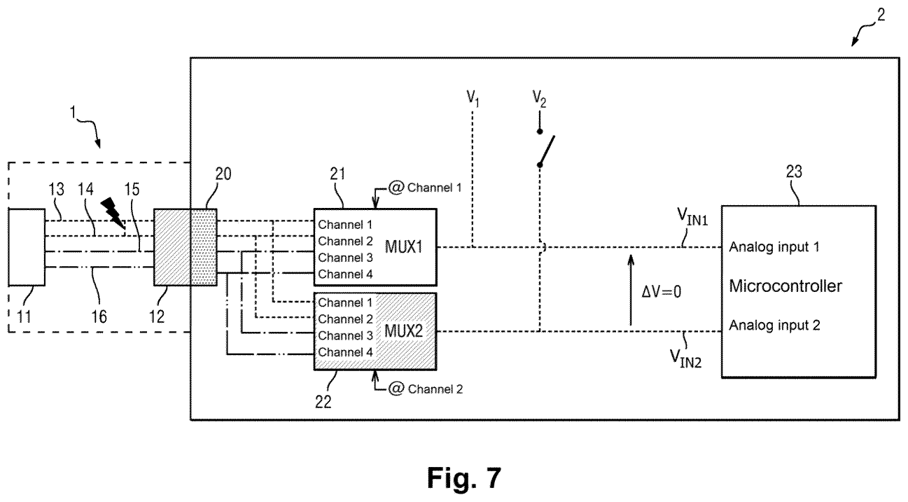

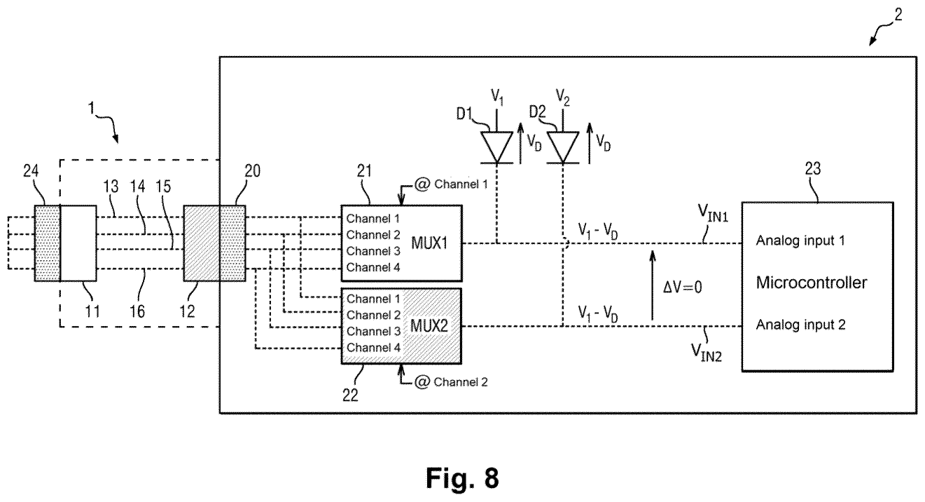

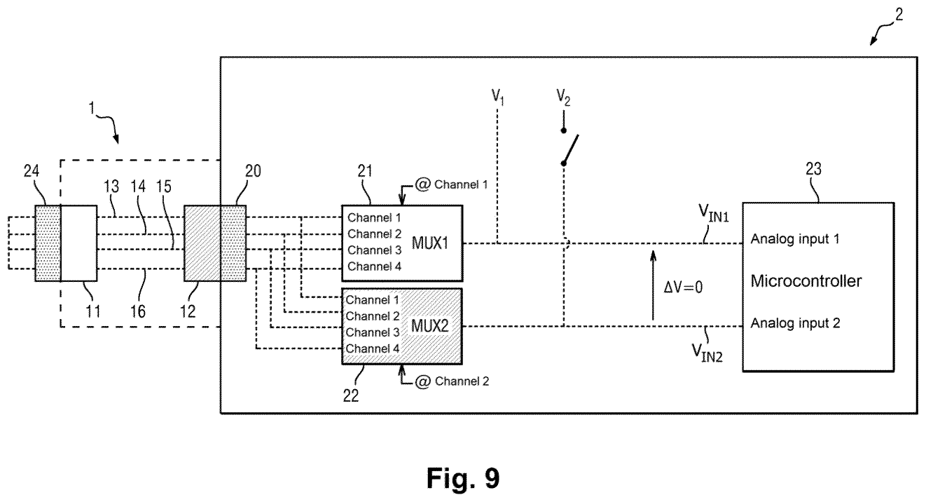

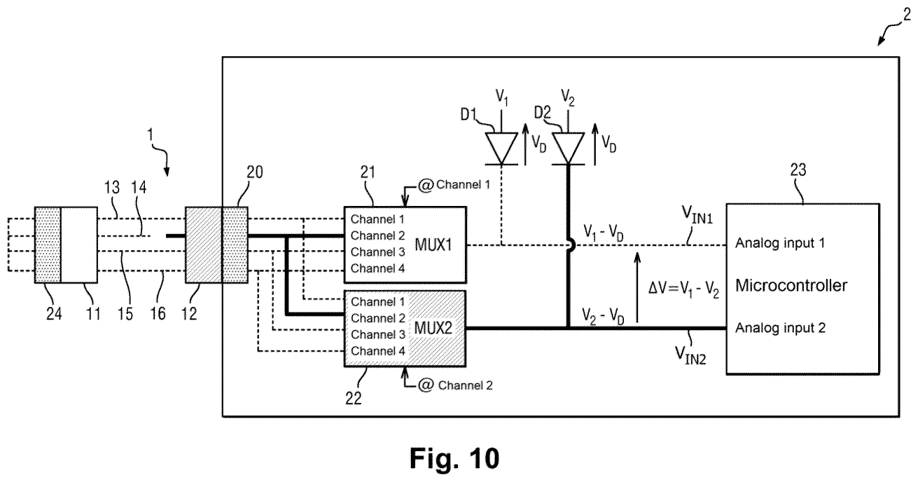

Then, during a step E43, the existence of an electrical fault in the cable network is deduced from the potential difference. The following examples, illustrated in FIGS. 5 to 10, detail the different faults that can be deduced from the potential difference:
the cable network does not have any short circuit (FIG. 5): the potential difference is non-zero, whatever the wire tested. It is therefore possible to deduce therefrom the absence of any short circuit in the harness 1;
the wires 13, 14, 15, 16 of the cable network are electrically connected to a single node and it does not have any open circuit (FIGS. 8 and 9): the potential difference is zero whatever the wire tested. It is therefore possible to deduce therefrom the absence of any open circuit in the harness 1;
the cable network has a short circuit between the wires 13 and 14 (FIGS. 6 and 7): the potential difference is zero when the addresses of the corresponding channels are selected. It is therefore possible to deduce therefrom the presence of a short circuit in the harness 1;
the wires 13, 14, 15, 16 of the cable network are electrically connected to a single node and the cable network has an open circuit between the wires 13 and 14 (FIG. 10): the potential difference is non-zero when the addresses of the corresponding channels are selected. It is therefore possible to deduce therefrom the presence of an open circuit in the harness 1 then the address of the damaged wire when the potential difference is computed for other combinations of channels.

Where applicable, the wires 13, 14, 15, 16 identified as being in an open circuit and/or in a short circuit can be displayed, for example on a simplified wiring diagram of the electrical harness 1.

The wires (13, 14, 15, 16) identified as being in an open circuit and/or in a short circuit can also be recorded, for example in a file configured for archiving or post-processing to improve the identification of the causes of malfunctions, or else to track a history of recurring malfunctions to deduce therefrom any variations in the behavior of the harness when it is in service.

1. A method for detecting an electrical fault in a cable network electrically connecting a first termination and a second termination of an electrical harness of an aircraft, the method comprising the following steps:
E1: connecting the cable network to channels of a first multiplexer and of a second multiplexer of a device for detecting an electrical fault of the electrical harness;
E2: supplying an anode of a first diode of the device at a first potential and an anode of a second diode of the device at a second potential different from the first potential;
the method further comprising, at each iteration of a plurality of iterations, performance of the following steps:
E41: selecting a first address of the first multiplexer and a second address of the second multiplexer;
E42: computing a potential difference between a cathode of the first diode and a cathode of the second diode; and
E43: determining from the potential difference an existence of an electrical fault in the cable network.

2. The method as claimed in claim 1, further comprising a step E3: configuring the first and second addresses of the channels of the first and second multiplexers, each address corresponding to a separate wire of the cable network.

3. The method as claimed in claim 1, further comprising a step E21: electrically connecting wires of the cable network to a single node.

4. The method as claimed in claim 1, further comprising a step E22: selecting a detection mode of the device.

5. The method as claimed in claim 1, wherein the channels of the first and second multiplexers are configured by loading a wiring diagram of the electrical harness recorded in a database.

6. The method as claimed in claim 1, further comprising a step E421: recording the first and second addresses and the potential difference.

7. The method as claimed in claim 1, wherein the plurality of iterations is at least equal to a number of combinations of a channel of the first multiplexer with a channel of the second multiplexer.

8. The method as claimed in claim 1, further comprising displaying the wires identified as being in an open circuit and/or a short-circuit.

9. The method as claimed in claim 1, further comprising recording the wires identified as being in an open circuit and/or a short circuit.

10. A device for detecting an electrical fault in a cable network electrically connecting a first termination and a second termination of an electrical harness of an aircraft, the device comprising:
a connection interface configured to connect the cable network to the device;
a first multiplexer and a second multiplexer configured to be electrically connected to the cable network;
a processing unit comprising a first input and a second input, the first input and the second input being configured to be electrically connected to the first multiplexer and to the second multiplexer respectively;
a first diode comprising a first anode configured to be connected to a voltage source at a first potential and a first cathode configured to be electrically connected to an output of the first multiplexer and the first input of the processing unit; and
a second diode comprising a second anode configured to be connected to a voltage source at a second potential and a second cathode configured to be electrically connected to an output of the second multiplexer and the second input of the processing unit, the second potential being different from the first potential;
wherein the processing unit is configured to:
select a first address of the first multiplexer and a second address of the second multiplexer;
compute a potential difference between the first cathode and the second cathode; and
determine from the potential difference an existence of an electrical fault in the cable network.

11. The device as claimed in claim 10, further comprising a means for interconnecting wires of the cable network to a single node.

12. The device as claimed in claim 10, wherein the voltage source is a local source or tapped from an electrical network of the aircraft.

13. A computer program product comprising instructions which, when is executed on a processing unit of a device for detecting an electrical fault in a cable network electrically connecting a first termination and a second termination of an electrical harness of an aircraft, the device comprising a connection interface configured to connect the cable network to the device, a first multiplexer and a second multiplexer configured to be electrically connected to the cable network, a first diode comprising a first anode configured to be connected to a voltage source at a first potential and a first cathode configured to be electrically connected to an output of the first multiplexer and the first input of the processing unit, and a second diode comprising a second anode configured to be connected to a voltage source at a second potential and a second cathode configured to be electrically connected to an output of the second multiplexer and the second input of the processing unit, the second potential being different from the first potential, causes the processing unit to implement the following steps:
E41: selecting a first address of the first multiplexer and a second address of the second multiplexer;
E42: computing a potential difference between a cathode of the first diode and a cathode of the second diode; and
E43: determining from the potential difference an existence of an electrical fault in the cable network.

14. A non-transitory computer readable medium that is readable by a computer, on which the computer program product as claimed in claim 13 is recorded.

15. The method as claimed in claim 4, wherein the selected detection mode of the device is a short circuit detection mode and/or an open circuit detection mode.

16. The method as claimed in claim 8, wherein the wires identified as being in an open circuit and/or a short-circuit are displayed on a simplified wiring diagram of the electrical harness.

17. The method as claimed in claim 9, wherein the wires identified as being in an open circuit and/or a short circuit are recorded in a file.
